(19) United States
(12) Patent Application Publication
(10) Pub. No.: US 2019/0072808 A1
(43) Pub. Date: Mar. 7, 2019

(54) DEVICE SUBSTRATE, LIQUID CRYSTAL DISPLAY APPARATUS, AND DEVICE SUBSTRATE MANUFACTURING METHOD

(71) Applicant: SHARP KABUSHIKI KAISHA, Sakai City, Osaka (JP)

(72) Inventor: MASAKI FUJIWARA, Sakai City (JP)

(73) Assignee: SHARP KABUSHIKI KAISHA, Sakai City, Osaka (JP)

(21) Appl. No.: 15/743,108

(22) PCT Filed: Jul. 14, 2016
(86) PCT No.: PCT/JP2016/070791

§ 371 Date: Jan. 9, 2018

(30) Foreign Application Priority Data
Jul. 21, 2015 (JP) 2015-144219

(51) Int. Cl. G02F 1/1333; G02F 1/1335; H01L 27/12

(52) U.S. Cl. CPC G02F 1/133305; H01L 27/1214; G02F 1/133514

(57) ABSTRACT

Device substrates 11, 12 are provided with: visible light transmissive flexible substrates 14, 15 which include one or a plurality of SiO films in accordance with spin-on-glass technology formed by curing a coating liquid containing a silanol compound including an alkyl group; and thin-film devices 16, 18 formed on the flexible substrates 14, 15.

### TECHNICAL FIELD

The present invention relates to a device substrate, a liquid crystal display apparatus, and a device substrate manufacturing method.

### BACKGROUND ART

In recent years, a flexible display equipped with a display unit of which the shape can be changed in a flexible manner is gaining attention. For example, in a flexible display of liquid crystal display type, the liquid crystal display panel has pliability and therefore can be bent when used. The liquid crystal display panel is provided with a thinner glass substrate, as compared with conventional liquid crystal display panels having a shape that does not change. The liquid crystal display panel has been commercially available in curved TVs.

During the manufacture of the liquid crystal display panel, because a glass substrate with a small thickness of not more than 0.5 mm has lower stiffness than conventional glass substrate, a thin-film layer (thin-film device), such as a thin-film transistor (TFT) or a color filter (CF), cannot be formed directly on the glass substrate.

According to a known method for manufacturing conventional liquid crystal display panels, the thickness of the glass substrate is set to a large value, such as 0.5 mm or more, in advance so as to ensure stiffness. After thin-film layers such as a TFT and a color filter (CF) are formed on the glass substrate, the glass substrate affixed with the thin-film layers is etched using a chemical solution so as to decrease the thickness of the glass substrate.

In another method that has been developed and proposed, a glass support substrate with a certain thickness is prepared separately from the glass substrate for forming the thin-film layer, and a thin glass substrate is attached to the support substrate using an adhesive or by other adhesive methods to form a thin-film layer on the glass substrate. Eventually, the thinner glass substrate is released from the support substrate.

Meanwhile, in the case of organic EL and the like, a structure is often employed in which an organic film of, e.g., polyimide (PI) or polyamide that has high thermal resistance/chemical resistance and that is obviously more flexible than glass is used, with a device formed thereon. In this case, as indicated in Patent Document 1, a method is known by which the organic film is formed on a glass support substrate, a thin-film layer (layer to be transferred) is formed thereon, and laser light such as excimer laser is irradiated from the support substrate side to release the thin-film layer and the support substrate from each other. According to the disclosure of Patent Document 1, in this method, as the laser light of a wavelength that a separation layer efficiently absorbs is irradiated, the material of which the separation layer is composed is instantaneously vaporized/evaporated and explosively emitted, whereby the bonding force between atoms or molecules is dissipated, and the thin-film layer and the support substrate are released from each other.

Methods also exist that include forming an organic material such as PI or polyamide on glass to fabricate a liquid crystal panel that is even more pliable, as in the case of an organic EL panel for a liquid crystal display apparatus. However, the material cannot be used due to the problem of visibility of the liquid crystal panel being greatly marred by a phase difference of the material, and it is necessary to use a thin glass substrate. A thin glass, however, is readily damaged by bending and lacks pliability, and its curvature is also limited for use in a limited range.

### PRIOR ART DOCUMENT

### Patent Document

Patent Document 1: Japanese Patent No. 3809833

### Problems to be Solved by the Invention

As discussed above, the method by which a thin glass substrate is attached to a thick glass support substrate via adhesive and then a thin-film layer of TFT and the like is laminated may result in contamination of the TFT manufacturing apparatus and the like due to components in the adhesive. In addition, with this method, it has been very difficult to develop a material that provides sufficient thermal resistance and chemical resistance while maintaining adhesiveness during the TFT process, based on the premise of eventual release from the support glass, and that, when exposed to high temperatures during the baking process, does not cause warping or cracking of the glass substrate, or a transfer failure due to the warped glass substrate interfering with surrounding objects during transfer, for example.

As discussed above, with the method by which the glass substrate is etched using a chemical solution to decrease the thickness of the glass substrate eventually, it has been difficult to uniformly control the thickness of the glass substrate, and it has been unable to obtain a very thin glass substrate (such as a glass substrate with a thickness on the order of 30 μm) that has increasingly been required in recent years. There has also been the problem of cost due to the issue of yield arising from the cost of the processing and damage to the glass being a thin substrate.

The above problems may be solved by the method whereby, instead of thin glass, an organic film of PI or polyamide and the like that is obviously more flexible than glass is formed to also serve as a separation layer, and the thin-film layer is released from the support substrate by utilizing laser light, whereby a highly flexible display may be advantageously braked. However, the visibility of the panel as a liquid crystal display apparatus would be significantly adversely affected by the phase difference of the material, and therefore it has been difficult to adopt the method.

### DISCLOSURE OF THE PRESENT INVENTION

An object of the present invention is to provide a technology which makes it possible to easily manufacture a device substrate and the like for a highly flexible liquid crystal display apparatus that has a thickness not achievable by conventional manufacturing methods and that does not mar visibility.

### Means for Solving the Problem

A device substrate according to the present invention includes a visible light transmissive flexible substrate including one or a plurality of SiO films obtained by curing a coating liquid containing a silanol compound including an alkyl group in accordance with spin-on-glass technology; and a thin-film device formed on the flexible substrate.

In the device substrate, the flexible substrate may include a single SiO film in accordance with spin-on-glass technology.

In the device substrate, the flexible substrate may include a single SiO film in accordance with spin-on-glass technology, and a single thermal resistance organic film formed on, of two surfaces of the SiO film, a surface on the thin-film device side or a surface on the opposite side from the thin-film device side.

In the device substrate, the flexible substrate may include two SiO films in accordance with spin-on-glass technology, and a single thermal resistance organic film interposed between the two SiO films.

In the device substrate, the flexible substrate may include a single SiO film in accordance with spin-on-glass technology, and two thermal resistance organic films respectively formed on two surfaces of the SiO film.

In the device substrate, the thermal resistance organic film may include polyimide or polyamide.

The liquid crystal display apparatus according to the present invention may include a color filter substrate including the device substrate. The color filter may not be provided with colored resin material, and may be based on a scheme in which a transparent resin is used to emit red, green, and blue light in sequence using a backlight.

The liquid crystal display apparatus may include a thin-film transistor array substrate including the device substrate.

According to the present invention, a method for manufacturing a device substrate for a liquid crystal display apparatus having a visible light transmissive flexible substrate and a thin-film device formed on the flexible substrate includes a photothermal conversion film forming step in which a photothermal conversion film is formed on a plate surface of a support substrate configured to transmit laser light and configured to support the device substrate, the photothermal conversion film generating neat by absorption of the laser light, being released from a film directly thereabove by the heat, and being made of a high melting-point metal or a high melting-point alloy; a flexible substrate forming step in which the flexible substrate is formed on the photothermal conversion film by coating a coating liquid for forming the flexible substrate on the photothermal conversion film, and curing a coating film including the coating liquid; a thin-film device forming step in which the thin-film device is formed on the flexible substrate and the device substrate fixed to the support substrate via the photothermal conversion film is obtained; an irradiating step in which laser light is irradiated from a surface side of the support substrate on which the thin-film device is not formed toward the photothermal conversion film, and in which adhesive force between the photothermal conversion film and the flexible substrate is dissipated or reduced; and a releasing step in which, after the adhesive force of the photothermal conversion film is dissipated and the like, the support substrate and the photothermal conversion film are released from the device substrate.

In the method for manufacturing a device substrate for a liquid crystal display apparatus, the photothermal conversion film may include a high melting-point metal or a high melting-point alloy including at least one selected from the group consisting of Ti, Mo, Ta, and W.

According to the present invention, a method for manufacturing a device substrate for a liquid crystal display apparatus having a visible light transmissive flexible substrate and a thin-film device formed on the flexible substrate includes a release layer forming step of forming a release layer on a plate surface of a support substrate configured to transmit laser light and configured to support the device substrate, the release layer being dissipated or pulverized by abrasion phenomenon of laser light; a flexible substrate forming step in which the flexible substrate is formed on the release layer using a coating liquid for forming the flexible substrate on the release layer, and curing a coating film including the coating liquid; a thin-film device forming step in which the thin-film, device is formed on the flexible substrate, and the device substrate fixed to the support substrate via the photothermal conversion film is obtained; an irradiating step in which laser light is irradiated from a surface side of the support substrate on which the thin-film device is not formed toward the release layer, and adhesive force between the release layer and the flexible substrate is dissipated or reduced; and a releasing step in which, after the adhesive force of the release layer is dissipated, the support substrate and the release layer are released from the device substrate.

In the method for manufacturing a device substrate for a liquid crystal display apparatus, the release layer may include a material that has large absorption of light of 300 nm to 400 nm selected from the group consisting of amorphous silicon, ITO, IZO, and In—Ga—Zn—O.

In the method for manufacturing a device substrate for a liquid crystal display apparatus, in the flexible substrate forming step, the coating liquid may contain a silanol compound including an alkyl group, and the coating film may form a SiO film containing an organic component after a heating reaction.

### Advantageous Effect of the Invention

The present invention provides a technology which makes it possible to easily manufacture a device substrate and the like for a highly flexible liquid crystal display apparatus that has a thickness not achievable by conventional manufacturing methods, and that does not mar visibility.

### BRIEF DESCRIPTION OF THE DRAWINGS

FIG. 1 is a diagram schematically illustrating a cross-sectional configuration of a liquid crystal display panel according to a first embodiment of the present invention;

FIG. 2 is a diagram schematically illustrating a step of forming a photothermal conversion film on a support substrate;

FIG. 3 is a diagram schematically illustrating a step of forming a flexible substrate on the photothermal conversion film;

FIG. 4 is a diagram schematically illustrating, on the CF substrate side, a step in which, with a CF substrate and a TFT array substrate affixed to each other while being fixed on support substrates, laser light is irradiated through the support substrate, and in which the absorbed optical energy is converted by a photothermal conversion film into thermal energy to dissipate adhesive force at the interface between the photothermal conversion film and the flexible substrate;

FIG. 5 is a diagram schematically illustrating, on the CF substrate side, a step in which the support substrate is released from the flexible substrate on the CF substrate side;

FIG. 6 is a diagram schematically illustrating a step of forming on a photothermal conversion film a PI film constituting a flexible substrate according to a second embodiment;

FIG. 7 is a diagram schematically illustrating a step of forming on the PI film a SiO film constituting a flexible substrate according to the second embodiment and obtained by SOG process;

FIG. 8 is a diagram schematically illustrating a step in which, with a CF substrate and a TFT array substrate affixed to each other while being fixed on support substrates, laser light is irradiated through the support substrate, and in which the absorbed optical energy is converted by a photothermal conversion film, into thermal energy to dissipate adhesive force at the interface with the flexible substrate according to the second embodiment;

FIG. 9 is a diagram schematically illustrating, on the CF substrate side, a step in which the support substrate is released from the flexible substrate on the CF substrate side according to the second embodiment;

FIG. 10 is a diagram schematically illustrating a step of forming on a photothermal conversion film a SiO film constituting a flexible substrate according to a third embodiment and obtained by SOG process;

FIG. 11 is a diagram schematically illustrating a step in which, with a CF substrate and a TFT array substrate affixed to each other while being fixed on support substrates, laser light is irradiated through the support substrate, and the absorbed optical energy is converted by a photothermal conversion film into thermal energy to dissipate adhesive force at the interface with a flexible substrate according to the third embodiment; and

FIG. 12 is a diagram schematically illustrating, on the CF substrate side, a step in which the support substrate is released from the flexible substrate on the CF substrate side according to the third embodiment.

### BEST MODE FOR CARRYING OUT THE INVENTION

### First Embodiment

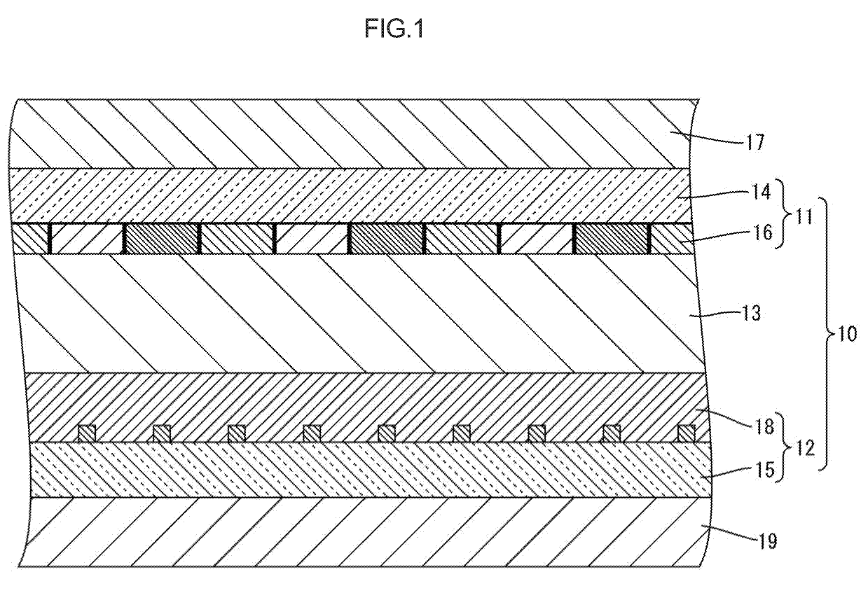

A first embodiment of the present invention will be described with reference to FIG. 1 to FIG. 5. In the present embodiment, as a method for manufacturing a device substrate for a liquid crystal display apparatus, a method for manufacturing a CF substrate 11 and a TFT array substrate 12 will be described by way of example. First, a liquid crystal display panel 10 (an example of liquid crystal display apparatus) including the CF substrate 11 and the TFT array substrate 12 will be described.

The liquid crystal display panel 10 is utilized in a flexible display, and has characteristics such as pliability and flexibility. FIG. 1 is a cross sectional diagram schematically illustrating a cross-sectional configuration of the liquid crystal display panel 10 according to the first embodiment of the present invention. As illustrated in FIG. 1, the liquid crystal display panel 10 mainly includes a pair of device substrates 11, 12 affixed so as to oppose each other, and a liquid crystal layer 13 interposed between the device substrates 11, 12. The liquid crystal display panel 10 is driven by active matrix system.

Between the device substrates 11, 12, the liquid crystal layer 13 is surrounded and sealed by sealing material which is not illustrated. The device substrates 11, 12 are affixed to each other by means of adhesive force and the like of the sealing material. The device substrates 11, 12 maintain a certain gap via a spacer which is not illustrated. The liquid crystal layer 13 contains liquid crystal molecules of which the optical characteristics can be varied by an electric field applied between the device substrates 11, 12.

The device substrates 11, 12 are respectively provided with thin, pliable, and light transmissive flexible substrates 14, 15. In the present embodiment, as the material of the flexible substrates 14, 15, a cured material of a liquid coating film containing a silanol compound based on an organic siloxane-based compound or an alkoxysilane-based compound and including an alkyl group, as used in spin-on-glass (SOG) technology, is utilized. By thermally curing the coating film (coated film), a silicon oxide-based coating film including organic matter cam be obtained. The silicon oxide-based coating film including organic matter is utilized as the flexible substrates 14, 15.

The thickness of the flexible substrates 14, 15 is not particularly limited, and may be set at 50 μm or less, for example.

The flexible substrates 14, 15 may be configured only from a silicon oxide-based thin-film (SiO film) including organic matter by SOG and the like. In another embodiment, as will be described later, the flexible substrates 14, 15 may be configured as a multilayer film in which one or a plurality of polyimide films (hereafter referred to as PI film) are laminated. When the flexible substrates are configured in the form, of a multilayer film of PI films, a smaller thickness of the PI film (film thickness) is preferable. The film thickness of the PI film is determined, as appropriate, by the flexible function of the product, while also taking into consideration the shape retention and self-supporting properties of the SiO film and the retardation, of the PI film, for example.

One of the device substrates 11, 12 is a CF substrate 11, and the other is a TFT array substrate 12. In the present embodiment, the CF substrate 11 is disposed on the front surface side (top of FIG. 1) of the liquid crystal display panel 10, and the TFT array substrate 12 is disposed on the back surface side (bottom of FIG. 1).

The CF substrate 11 includes a CF-side thin-film layer (an example of thin-film device) 16 which comprises a laminated material of, e.g., CF layers colored in red, green, blue and the like using pigment on acrylic resin, and which is formed on a surface (inner surface) on the liquid crystal layer 13 side of the flexible substrate 14. The CF-side thin-film layer 16 is configured from, e.g., a CF layer, a black matrix layer, an alignment film, and opposite electrodes. To the surface (outer surface) of the CF substrate 11 on the front surface side (outer side), a polarizing plate 17 is attached.

The TFT array substrate 12 includes a TFT-side thin-film layer (an example of thin-film device) 18 which is made of a laminated material of TFTs and the like and which is formed on a surface (inner surface) on the liquid crystal layer 13 side of the flexible substrate 15, which is configured from the material indicated for the flexible substrate 14 by way of example. The flexible substrate 15 and the flexible substrate 14 are not necessarily required to have the same configuration and film thickness. The TFT-side thin-film layer 18 is configured from, e.g., TFTs composed of an oxide semiconductor film, pixel electrodes composed of a transparent electrically conductive film, wiring composed of a metal thin-film such as gate wiring, source wiring, and capacity wiring, an insulating layer, a protection film, a barrier film, a resin spacer for ensuring a certain cell gap, and an alignment film. To the surface (outer surface) on the back surface; side (outer side) of the TFT array substrate 12, a polarizing plate 19 paired with the polarizing plate 17 on the CF substrate 11 side is attached.

The steps of a method for manufacturing the liquid crystal display panel 10 will be described. Herein, an example in which the flexible substrates 14, 15 only include a SiO film obtained by SOG process will be described. First, a step of manufacturing the TFT array substrate 12 will be described.

### (Photothermal Conversion Film Forming Step)

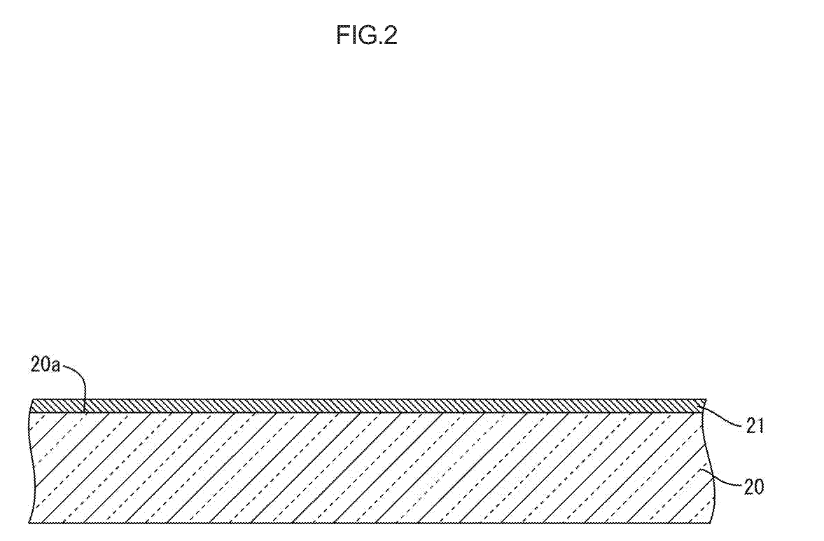

FIG. 2 is a diagram schematically illustrating the step of forming, on the support substrate 20, a photothermal conversion film 21 made of a high melting-point metal or a high melting-point alloy including at least one selected from, the group consisting of Ti, Mo, Ta, and W. The support substrate 20 is a plate-shaped material utilized as a base for forming the TFT array substrate 12. The support substrate 20 has a large thickness compared with the flexible substrate 15, and has stiffness to retain its shape by itself. The support substrate 20 is required to be transmissive with respect to laser light irradiation. The support substrate 20 may include known glass, such as alkali-free glass or quartz glass. Adoption of an alkali-free glass of a size used for manufacturing existing liquid crystal display device may make it possible to use conventional equipment as is for the manufacture, and may eliminate the need for developing special dedicated apparatus.

As illustrated in FIG. 2, the support substrate 20 is arranged and then the photothermal conversion film 21 is formed on one surface (inner surface) 20a thereof. The photothermal conversion film is made of a material that sufficiently absorbs a wavelength of laser light that sufficiently passes through the support substrate, and is formed by forming a film of high melting-point metal or metal alloy and the like by sputtering, for example. The film thickness may vary depending on the transmission characteristics and may need to be at least 100 nm.

In another example of manufacture, a release layer may be used instead of the photothermal conversion film 21. The release layer has material which, when irradiated with laser light, instantaneously vaporizes and evaporates and is explosively released (abrasion phenomenon), whereby the adhesive force is dissipated or reduced, or the film itself is dissipated or pulverized, thereby releasing the support substrate 20 from the other laminated material. For example, a release layer of amorphous silicon or ITO is irradiated with laser with a wavelength of 355 nm or 308 nm.

### (Flexible Substrate Forming Step)

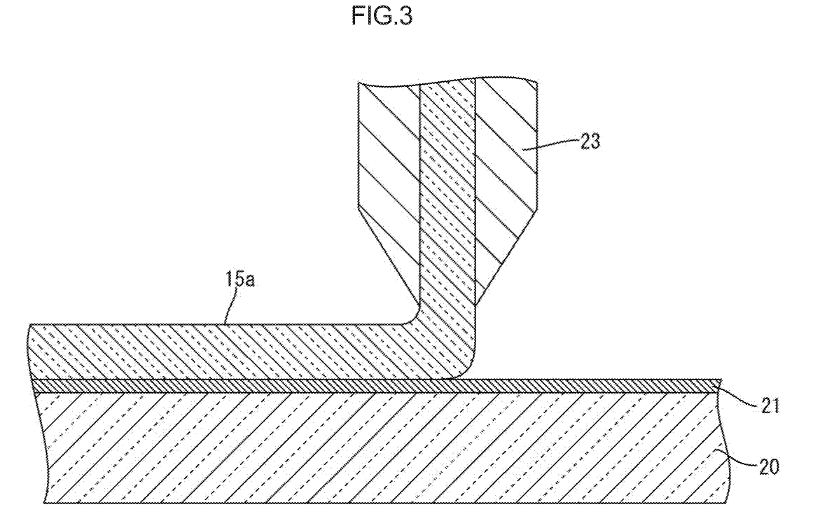

After the photothermal conversion film 21 is formed on the support substrate 20 as described above, the flexible substrate 15 is formed so as to be laminated with the photothermal conversion film 21. FIG. 3 is a diagram schematically illustrating the step of forming the flexible substrate 15 on the photothermal conversion film 21.

The flexible substrate 15, as described above, includes a film formed by SOG technology, such as a silicon oxide-based film including organic matter obtained by thermally curing a liquid coating film containing a silanol compound based on an organic siloxane-based compound and including an alkyl group. Before a SOG material is coated, in order to improve sticking force, surface reforming is performed through UV lamp irradiation or oxygen plasma exposure for pretreatment for adhesion improvement, and then the photothermal conversion film 21 is coated. An additive for sticking force enhancement may be mixed in the SOG material. The method for coating the SOG material 15a is not particularly limited, and may preferably include the use of a slit coater depicted as a coater 23 such as a spin coater for reasons including, for example, the ease with which the thickness of the resultant flexible substrate 15 can be uniformly controlled.

After the coating film made of the SOG material 15a is formed, a heating process (baking process) is implemented to cause a coating film reaction, whereby the flexible substrate 15 including a thin-film of organic matter and SiO as a principal component is obtained. The heating process (baking process) is implemented at a temperature of not lower than 200° C., for example.

The thickness of the flexible substrate 15 is not particularly limited, and may be set as appropriate in accordance with the purpose. For example, the thickness may be set on the order of 1 μm to 50 μm. The flexible substrate 15 is formed basically entirely with respect to the photothermal conversion film 21 on the support substrate 20.

Because the flexible substrate 15 is formed from SiO as a principal component, the flexible substrate 15 does not cause a decrease in visibility, which is important for a liquid crystal display apparatus, due to phase difference. Measurements actually taken of the phase difference indicated an unmeasurable level.

(Thin-Film, Device Forming Step)

After the flexible substrate 15 is formed on the photothermal conversion film 21, the constituent elements of the TFT-side thin-film layer 18 are formed on the flexible substrate 15 while being patterned in a predetermined shape using known film formation technology, photolithography technology and the like.

A barrier film 18a serves to prevent organic components in the film of the flexible substrate 15 from moving toward the TFT-side thin-film layer 18. Because the TFTs and the like included in the TFT-side thin-film layer 18 is possibly susceptible to the influence of the organic components, the barrier film 18a is formed so as to cover the surface of the flexible substrate 15. Examples of the barrier film 18a include a silicon nitride (SiN) film and a silicon nitride oxide film (SiNO). The barrier film 18a is formed to a thickness on the order of 50 nm to 500 nm, for example. It should be noted that the barrier film 18a is not an indispensable constituent element, and may be provided as needed or appropriate.

When the TFT-side thin-film layer 18 including the barrier film 18a and the like is formed on the flexible substrate 15, the TFT array substrate 12 (thin-film device attached with a support substrate) is obtained on the flexible substrate 15 fixed on the support substrate 20 and having flexibility.

With regard to the CF substrate 11, as in the case of the TFT array substrate 12 described above, the CF substrate 11 is formed on the support substrate 20 via the photothermal conversion film 21. That is, the photothermal conversion film 21 is formed on the support substrate 20, and the flexible substrate 14 is formed on the photothermal conversion film 21 by a method similar to that in the case of the flexible substrate 15 described above. Then, the CF-side thin-film, layer 16 is formed on the flexible substrate 14, whereby the CF substrate 11 is obtained on the flexible substrate 15 fixed, to the support substrate 20 and having flexibility.

With regard to the CF substrate 11, as in the case of the TFT array substrate 12, a release layer may be used instead of the photothermal conversion film 21.

(Affixing Step)

Then, the CF substrate 11 and the TFT array substrate 12 each fixed to the support substrate 20 is affixed to each other, so as to sandwich the liquid crystal layer 13. The CF substrate 11 and the TFT array substrate 12 are fixed to each other by utilizing the adhesive force and the like of a sealing material interposed therebetween and surrounding the liquid crystal layer 13. The CF substrate 11 and the TFT array substrate 12 are affixed to each other by a known method or technique.

Thus, the CF substrate 11 and the TFT array substrate 12 can be affixed to each other with the substrates still fixed to the support substrate 20, which is stronger than the flexible substrates, whereby the state of the liquid crystal display 10 is achieved. Accordingly, superior operatability, workability, transferability and the like of the CF substrate 11 and the TFT array substrate 12 can be obtained. In addition, the manufacturing method of the present embodiment can be implemented using a conventional liquid crystal display device manufacturing apparatus and method.

(Irradiating Step and Releasing Step)

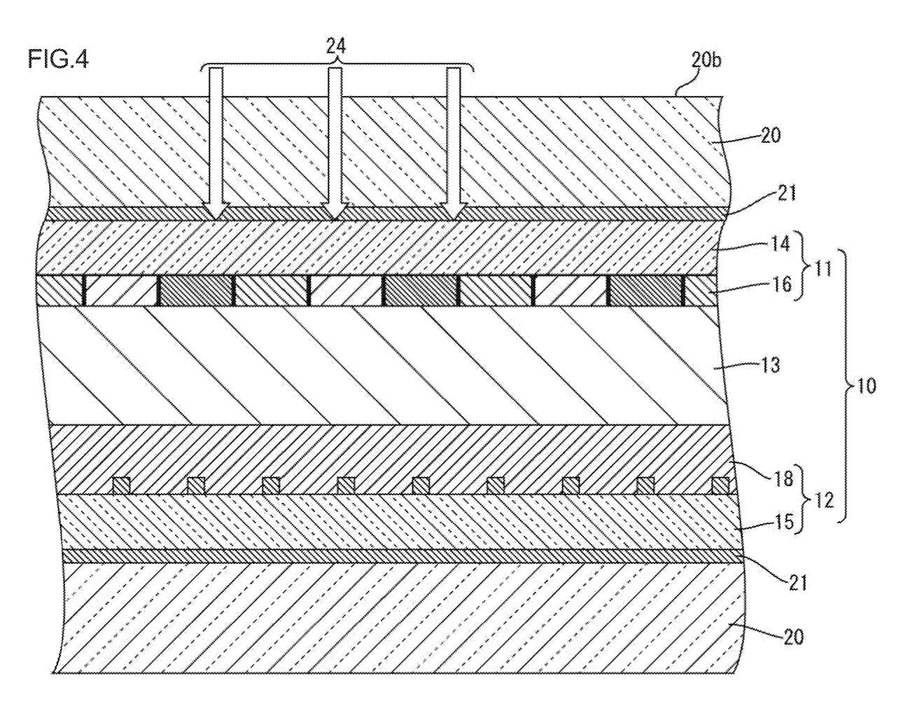

FIG. 4 is a diagram schematically illustrating, on the CF substrate 11 side, the step in which, with the CF substrate 11 and the TFT array substrate 12 affixed to each other while being fixed to the support substrate 20, laser light 24 is irradiated through the support substrate 20, and the absorbed optical energy is converted by the photothermal conversion film 21 into thermal energy to dissipate adhesive force at the interface between the photothermal conversion film 21 and the flexible substrate 14. As illustrated in FIG. 4, in order to release the support substrate 20 from the liquid crystal display panel 10, irradiation of the laser light 24 is performed.

In this step, the photothermal conversion film 21 on the CF substrate 11 side and the photothermal conversion film 21 on the TFT array substrate 12 side are respectively irradiated with the laser light 24 through the support substrate 20. The light is absorbed and turned into heat, and the heat causes melting at the interface and an expansion/contraction difference due to a difference in linear expansion coefficient. As a result, the support substrate 20 with one photothermal conversion film 21 attached thereto is released from the flexible substrate 14 on the CF substrate 11 side. With a shape maintained by the support substrate 20 on the TFT array substrate 12 side which is stronger than the flexible substrates, a polarizing plate is affixed. Thereafter, laser irradiation is performed by a similar method from the support substrate 20 side of the TFT array 12, and the photothermal conversion film 21 and the support substrate 20 are released from the flexible substrate 15 on the TFT array substrate 12 side.

Concerning the type of the laser light 24, a laser with a wavelength that passes through the support substrate 20 and at which sufficient energy for the releasing can be absorbed by the photothermal conversion film 21 is used. For example, a UV laser or a green laser in a range that passes through the support substrate 20 may be used. While the type of laser is not particularly limited besides wavelength, a pulsed laser with a pulse width of several dozen nsec rather than a CW laser makes it possible to decrease thermal influence in the film thickness direction. In a demonstration of the present case, a 355 nm solid-state laser with a pulse width of 20 nsec, a 308 nm excimer laser with a pulse width of 30 nsec, and a 532 nm solid-state laser with a pulse width of 10 nsec were used to release the support substrate 20 with the photothermal conversion film 21 attached thereto from the flexible substrate 14 on the CF substrate 11 side and the flexible substrate 15 on the TFT array substrate 12 side.

In another example of manufacture, when a release layer is adopted instead of the photothermal conversion film 21, a laser is selected that passes through the support substrate 20 and is able to irradiate a wavelength that is sufficiently absorbed by the release layer. When the laser light 24 is irradiated from the support substrate 20 side, the laser light 24 passes through the support substrate 20 and irradiates the release layer. The release layer absorbs the laser light 24 and instantaneously evaporates (abrasion), whereby the release layer is dissipated or pulverized, and the support substrate 20 and the flexible substrate 14 are separated. For example, when the release layer is made of amorphous silicon, a UV solid-state laser of 355 nm that is easily absorbed may be used for the irradiation.

When the laser light 24 is irradiated toward the liquid crystal display panel 10, the laser light 24 may be irradiated from one side and then the other side, or the laser light 24 may be irradiated from both sides simultaneously.

In addition, because the liquid crystal display panel 10 attached with the support substrate 20 is irradiated with the laser light 24 by a method involving wide-area irradiation, productivity can be greatly improved with the use of a line beam or a galvano scan scheme in an optical system.

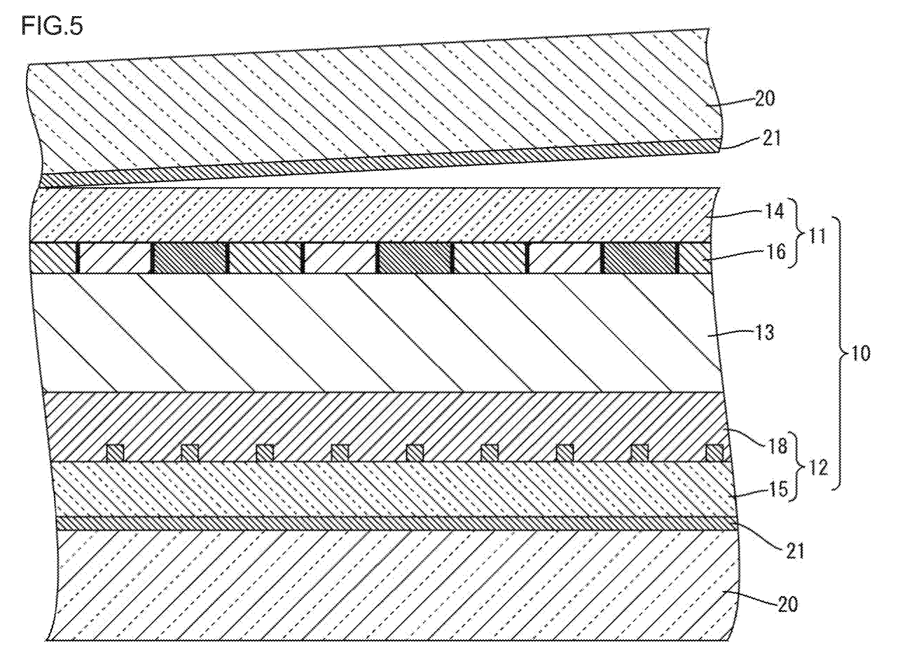

FIG. 5 is a diagram schematically illustrating, on the CF substrate 11 side, the step in which the support substrate 20 is released from the flexible substrate 14 on the CF substrate 11 side. As described above, when the predetermined laser light 24 is irradiated from the outer side of the support substrate 20 toward the photothermal conversion film 21 on the CF substrate 11 side, the laser light 24 passes through the support substrate 20 and reaches the photothermal conversion film 21, and the adhesion (fixing) between the support substrate 20 and the flexible substrate 14 is eliminated by the neat generated by the photothermal conversion film 21. As a result, the support substrate 20 can be easily released from the liquid crystal display panel 10 side.

Also with regard to the support substrate 20 on the TFT array substrate 12 side, the laser light 24 is similarly irradiated from the outer side of the support substrate 20 toward the back surface (outer surface) 20b of the support substrate 20 to cause the photothermal conversion film 21 to generate heat, whereby the support substrate 20 can be released from the flexible substrate 15 on the TFT array substrate 12 side.

The surfaces of the flexible substrates 14, 15 after the support substrate 20 has been removed may be cleaned, as appropriate, to remove residual material. The cleaning of the surface of the flexible substrate 14 is not indispensable, and the residual material may be left as is to the extent that the residual material does not affect the display performance of the liquid crystal display panel 10. Particularly when a release layer instead of the photothermal conversion film 21 is adopted, debris may be produced by abrasion and visibility may be marred. In this case, cleaning is often performed to remove residual material.

As described above, the liquid crystal display panel 10 intended for flexible display and equipped with the flexible substrates 14, 15 having a small thickness on the order of 1 μm to 50 μm is obtained. On both outer sides of the liquid crystal display panel 10, as illustrated in FIG. 1, the polarizing plates 17, 19 are eventually attached by means of adhesive such as pressure-sensitive adhesive.

When the support substrate 20 is released from the liquid crystal display panel 10 side, one support substrate 20 may be released first, and, before releasing the other support substrate 20, a polarizing plate (such as the polarizing plate 17) may be attached to the flexible substrate on the released side (such as the flexible substrate 14), as a support member. Then, after the polarizing plate is attached, the other support substrate 20 may be released and the remaining polarizing plate (such as the polarizing plate 19) may be attached to the flexible substrate (such as the flexible substrate 15). By thus releasing the support substrate 20 and attaching a polarizing plate in place of the support substrate 20, the stiffness, operatability and the like of the liquid crystal display panel 10 may be ensured.

As described above, according to the manufacturing method of the present embodiment, the flexible substrates 14, 15 including silicon oxide-based films including organic matter are formed on the support substrate 20 via the release layer 21, and the thin-film devices (the CF-side thin-film layer 16 and the TFT-side thin-film layer 18) are formed on the flexible substrates 14, 15. Accordingly, it is possible to easily manufacture the liquid crystal display panel 10 intended for flexible display and having a small thickness that cannot be achieved by conventional manufacturing methods.

### Second Embodiment

In the present embodiment, a case will be described by way of example in which the flexible substrates 14A, 15A include a laminated material of a SiO film and a PI film obtained by SOG process. In the following embodiments, configurations similar to those of the first embodiment will be designated with similar signs and their detailed descriptions will be omitted.

In the first embodiment, the SOG film (SiO film) single layer including SiO as a principal component is almost free of phase difference and has high visibility. The layer, however, has a high modulus of elasticity and lacks crack resistance, resulting in the disadvantage of being susceptible to breaking due to, e.g., film defect caused by particles introduced into the film, or partial irradiation failure during laser irradiation caused by the shadows of particles in the releasing step. Accordingly, in order to improve shape retention and self-supporting property, a thin PI film of not more than 3 fim that does not mar visibility is configured as a reinforcing material in a laminate structure with the SOG film (SiO film). The structure makes it possible to greatly improve self-supporting property.

In the present embodiment, flexible substrates 14A, 15A are configured in a SiO film/PI film structure with the PI film provided on the support substrate side, or a PI film/SiO film/PI film structure with the PI films provided on both sides of the SiO film.

(Photothermal Conversion Film Forming Step)

As in the photothermal conversion film forming step of the first embodiment, the photothermal conversion film 21 made of a high melting-point metal or a high melting-point alloy is formed on the support substrate 20.

Because a PI film absorbs UV light, in another example of manufacture, the photothermal conversion film 21 may not be formed when a laser of a wavelength range that passes through the support substrate 20 and is absorbed by the PI film is used for releasing. For example, inorganic glass is used for the support substrate, and a PI film is formed directly over the support substrate. Generally, inorganic glass used in liquid crystal devices transmits 30 to 80% at 300 nm and a PI film begins to absorb at 400 nm or below. Accordingly, by means of irradiation using a 355 nm solid-state laser or a 308 nm excimer laser, it becomes possible for the laser to pass through the support substrate (inorganic, glass) and to cause the PI film to be directly released by abrasion. However, causing the PI film to be directly released by abrasion may generate debris, and visibility may be marred. Further, irregularities reflecting the intensity distribution of the laser irradiation tend to be caused, which, possibly in association with the phase difference of the PI film, may cause a decrease in visibility in a liquid crystal display device. Accordingly, the technique involving the photothermal conversion film 21 as in the present embodiment is desirable.

### (Flexible Substrate; Forming Step)

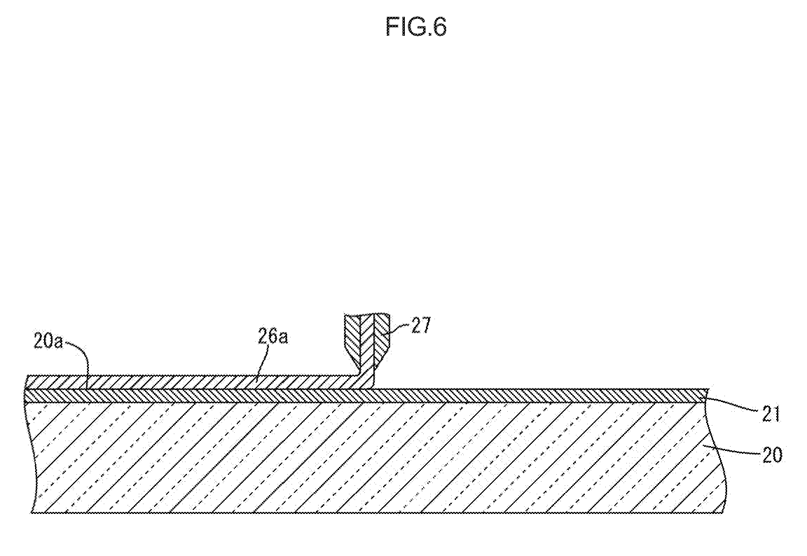

As described above, after the photothermal conversion film 21 is formed on the support substrate 20, a flexible substrate 15A is formed so as to be laminated with the photothermal conversion film 21. FIG. 6 is a diagram schematically illustrating the step of forming a PI 26 film constituting the flexible substrate 15A according to the second embodiment on the photothermal conversion film 21.

The flexible substrate 15A, as described above, may include an organic material having high thermal resistance, such as PI. In this case, preferably the PI to be used is a material that, through the framework structure of major materials and additives and the like, is able to transmit visible light as much as possible, has transparency, and has small phase difference. On the PI, a film is used which is formed by SOG technology, such as a silicon oxide-based film including organic matter that is obtained by thermally curing a liquid coating film that contains a silanol compound based on an organic siloxane-based compound and that includes an alkyl group.

In order to maintain adhesion on the support substrate 20 having the photothermal conversion film 12 formed thereon, pretreatment is performed by, for example, exposing a hexamethyldisiloxane (HMDS) reagent to steam or applying a silane coupling agent by use of a spin coater, and then PI is formed. For the PI, a precursor polyamide acid (polyamic acid) dissolved in solvent is entirely applied using a coater 27, such as a slit coater or a spin coater. An applied material 26a is heated to 200° C. or above to perform imidization, whereby the PI film 26 is formed. The PI film has a film thickness that provides the eventually obtained flexible substrate 15A with a required strength. From the viewpoint of reducing phase difference, the smaller the film thickness, the better. Preferably, the film thickness may be 0.5 μm to 3 μm. In an implementation prototype, the PI films with thicknesses of 1 μm and 2 μm were formed using a special PI having a small phase difference and being colorless and transparent, and then a SOG was laminated to a film thickness of 10 μm, where the phase difference was not more than 10 nm, which is a level that would pose no problem for use in a liquid crystal display.

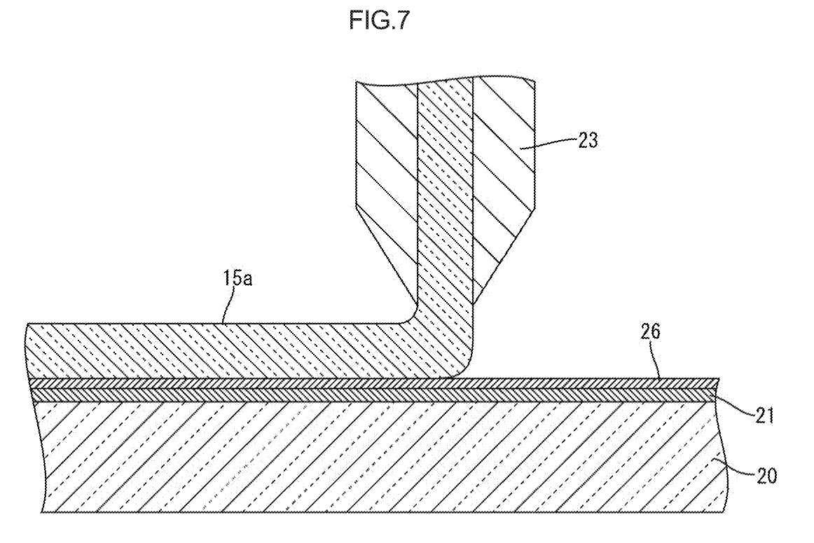

Then, before coating the SOG material, in order to improve sticking force, adhesion improvement pretreatment is performed by surface reforming through, e.g., UV lamp irradiation or oxygen plasma exposure. Thereafter, the SOG material is applied on the PI film 26. FIG. 7 is a diagram schematically illustrating the step of forming a SiO film 150 constituting the flexible substrate 15A according to the second embodiment on the PI film 26.

The method for coating the SOG material 15a is not particularly limited. However, for reasons such as the ease with which the thickness of the eventually obtained flexible substrate 15A can be uniformly controlled, a slit coater or a spin coater indicated by the coater 23 is preferable.

After the coating film made of the SOG material 15a is formed, heating process (baking process) is implemented, whereby the coating film undergoes a reaction and the SiO film (SOG film) 150 composed of the silicon oxide-based thin-film including organic matter and SiO as a principal component is obtained. The SiO film is formed to have a film thickness of not more than 50 μm and that is not particularly limited. From the viewpoint of effectively utilizing the characteristic of each film, the film thickness may be smaller than that of the PI film 26. The heating process (baking process) is implemented at the temperature of 200° C. or above. With respect to an implementation prototype, an SOG with a film thickness of 10 μm was formed on the PI films 26 of 1 μm and 2 μm, where, compared with a SOG single layer, about 15 times higher-breaking strength was obtained.

The PI film 26 is generally a material with high thermal resistance and chemical resistance. However, it is difficult to develop a material that can withstand the plasma for manufacturing a TFT element or the step of releasing a resist that is organic matter. Particularly, it is more difficult to develop a material with which visible light transparency and phase difference reduction can be achieved, both of which are indispensable in a liquid crystal display device. Thus, the SOG/PI structure in which the SOG material whose principal component includes SiO and whose processing resistance is high is coated/formed on the PI film also provides the advantage of simplifying PI material development.

Further, for the purpose of improving the shape retention and self-supporting properties of the flexible substrate 15A, in another example of manufacture, a three-layer structure may be adopted in which a PI film is additionally provided on the SOG film (SiO film)/PI film. For the formation of the upper-layer PI, as in the formation of the lower-layer PI described above, processing for improving adhesion with the SOG film is performed by surface reforming through UV lamp; irradiation or oxygen plasma exposure as a pretreatment. Thereafter, a PI precursor polyamide acid (polyamic acid) dissolved in solvent is entirely applied on the SOG film, and then imidization is performed by heating to 200° C. or above, whereby PI is formed. As described above, the smaller the film thickness of the PI, the better from the viewpoint of phase difference reduction, and the film thickness is preferably not more than 3 μm. The film thickness may differ from the film thickness of the lower-layer PI film.

The thickness of the flexible substrate 15A is not particularly limited, and may be set as appropriate in accordance with the purpose. For example, the thickness may be on the order of 1 μm to 50 μm. The flexible substrate 15A is basically entirely formed with respect to the photothermal conversion film 21 on the support substrate 20.

### (Thin-Film Device Forming Step)

After the flexible substrate 15A is formed on the photothermal conversion film 21, as in the thin-film device forming step of the first embodiment, the constituent elements of the TFT-side thin-film layer 18 are patterned and formed on the flexible substrate 15A in a predetermined shape by utilizing known film formation technology, such as photolithography technology.

When the TFT-side thin-film layer 18 is formed on the flexible substrate 15A, the TFT array substrate 12 fixed to the support substrate 20 (thin-film device attached with a support substrate) is obtained.

Also with regard to the CF substrate 11, similarly to the case of the TFT array substrate 12 described above, the CF substrate 11 is formed via the photothermal conversion film 21 on the support substrate 20. That is, the photothermal conversion film 21 is formed on the support substrate 20, and, on the photothermal conversion film 21, by a method similar to that in the case of the above-described flexible substrate 15A, a flexible substrate 14A of the two-layer structure of SiO film 140/PI film 26 is formed. Then, the CF-side thin-film layer 16 is formed on the flexible substrate 14A, whereby the CF substrate 11 still fixed to the support substrate 20 is obtained. The flexible substrate 15A on the TFT array substrate side and the flexible substrate 14A on the CF substrate side may not necessarily have the same configuration or film thickness, and may be implemented in other ways.

### (Affixing Step)

As in the first embodiment, the CF substrate 11 and the TFT array substrate 12 each fixed to the support substrate 20 are affixed to each other so as to sandwich the liquid crystal layer 13. In this way, the CF substrate 11 and the TFT array substrate 12 are affixed to each other with the substrates still fixed to the support substrates 20, which are stronger than the flexible substrates 14A, 15A, whereby the state of the liquid crystal display panel 10 is achieved. Accordingly, superior operatability, workability, transferability and the like of the CF substrate 11 and the TFT array substrate 12 are obtained. In addition, the manufacturing method of the present embodiment can be implemented using a conventional liquid crystal display device manufacturing apparatus and method.

### (Irradiating Step and Releasing Step)

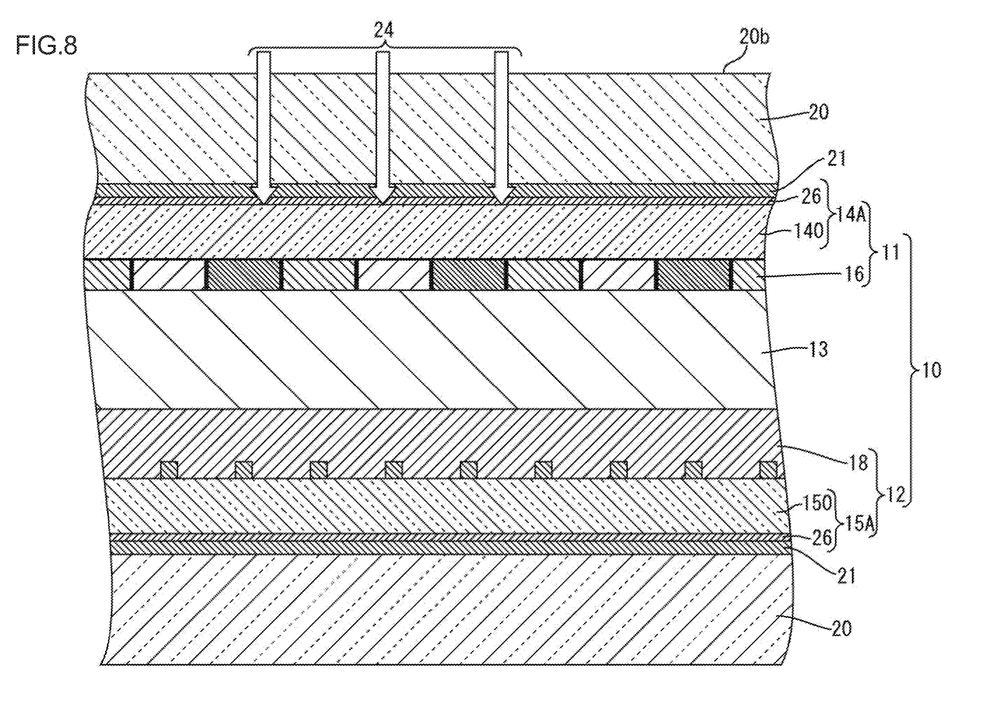

FIG. 8 is a diagram schematically illustrating the step in which, with the CF substrate 11 and the TFT array substrate 12 affixed to each other while being fixed to the support substrate 20, the laser light 24 is irradiated through the support substrate 20, and the absorbed optical energy is converted by the photothermal conversion film 21 into thermal energy to dissipate adhesive force at the interface between the photothermal conversion film 21 and the flexible substrate 14A according to the second embodiment. As illustrated in FIG. 8, as in the first embodiment, in order to release the support substrate 20 from the liquid crystal display panel 10, irradiation of the laser light 24 is performed.

In this step, the photothermal conversion film 21 on the CF substrate 11 side and the photothermal conversion film 21 on the TFT array substrate 12 side are respectively irradiated with the laser light 24 each through the support substrate 20. The light is absorbed and turned into heat, and the heat causes melting at the interface and an expansion/contraction difference due to a difference in linear expansion coefficient. As a result, the support substrate 20 with one photothermal conversion film attached thereto is released from the flexible substrate 14A on the CF substrate 11 side. With a shape maintained by the support substrate 20 on the TFT array substrate 12 side that is stronger than the flexible substrate, a polarizing plate is affixed. Thereafter, by a similar method, laser irradiation is performed from the support substrate 20 side of the TFT array 12 to release the photothermal conversion film 21 and the support substrate 20 from the flexible substrate 15A on the TFT array substrate 12 side.

With regard to the type of the laser light 24, as in the first embodiment, a laser with a wavelength which passes through the support substrate 20 and at which sufficient energy for releasing can be absorbed by the photothermal conversion film 21 is used. When the laser light 24 is irradiated toward the liquid crystal display panel 10, the laser light 24 may be irradiated from one side and then the other side, or the laser light 24 may be irradiated from both sides simultaneously.

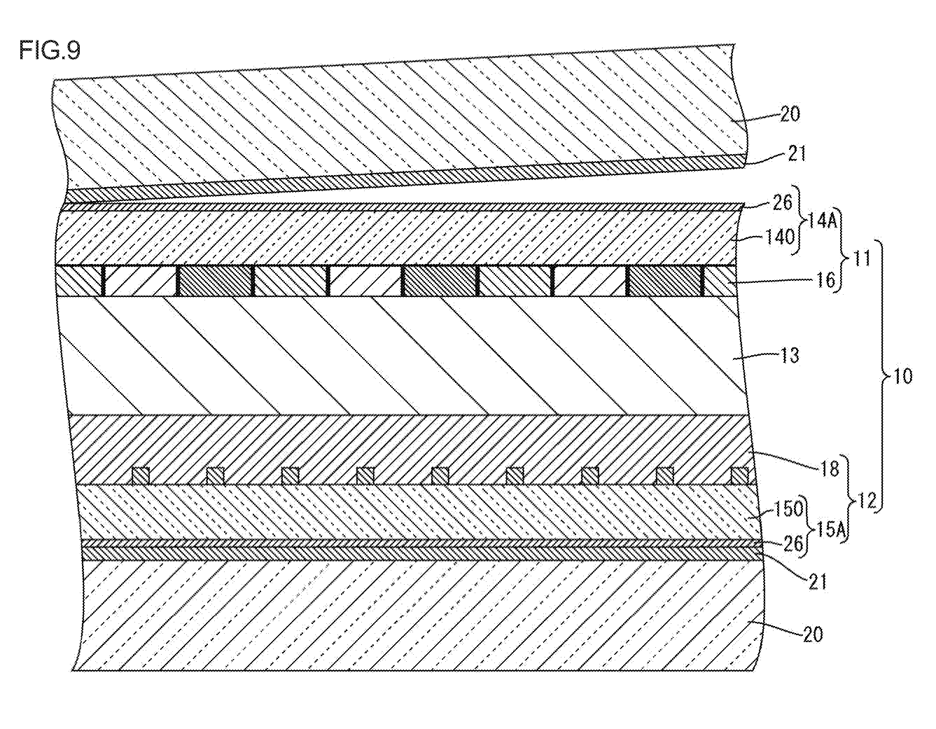

FIG. 9 is a diagram schematically illustrating, on the CF substrate 11 side, the step in which the support substrate 20 is released from the flexible substrate 14A on the CF substrate 11 side according to the second embodiment. As described above, when the predetermined laser light 24 is irradiated from the outer side of the support substrate 20 toward the release layer 21 on the CF substrate 11 side, the laser light 24 passes through the support substrate 20 and reaches the photothermal conversion film 21. By the heat generated by the photothermal conversion film 21, the adhesion (fixing) between the support substrate 20 and the flexible substrate 14A is eliminated. As a result, the support substrate 20 can be easily released from, the liquid crystal display panel 10 side.

Also with regard to the support substrate 20 on the TFT array substrate 12 side, similarly, the laser light 24 is irradiated from the outer side of the support substrate 20 toward, the back surface of the support substrate 20 (outer surface) 20b to cause the photothermal conversion film 21 to generate heat, whereby the support substrate 20 can be released from, the flexible substrate 15A on the TFT array substrate 12 side.

After the support substrate 20 has been removed, the surfaces of the flexible substrates 14A, 15A may be cleaned, as appropriate, to remove residual material. Particularly, residual material needs to be removed in the case of the releasing method by which the PI film is directly released by abrasion through the support substrate (inorganic glass) as described above, where debris is produced.

As described above, the liquid crystal display panel 10 intended for flexible display and equipped with the flexible substrates 14A, 15A having a small thickness on the order of 1 μm to 50 μm is obtained. On both outer sides of the liquid crystal display panel 10, the polarizing plates 17, 19 as illustrated in FIG. 1 for the first embodiment are eventually attached by means of an adhesive such as pressure-sensitive adhesive.

### Third Embodiment

In the present embodiment, a case will be described by way of example in which the flexible substrates 14B, 15B include a laminated material of a PI film and a SOG film. In the present embodiment, the flexible substrates 14B, 15B are configured in a laminate structure of a PI film and a SOG film (SiO film), whereby shape retention and self-supporting properties are also greatly improved.

In the second embodiment, the PI film was formed directly over the support substrate. In the present embodiment, a configuration will be described by way of example in which the SOG (SiO film) is formed directly over the support substrate. In this case, the flexible substrates 14B, 15B may be configured in a PI film/SiO film structure with the SOG (SiO film) disposed on the support substrate side, or a SiO film/PI film/SiO film structure. In the present embodiment, the two-layer structure of PI film/SiO film will be described by way of example.

### (Photothermal Conversion Film Forming Step)

As in the photothermal conversion film forming step of the first embodiment, the photothermal conversion film 21 is formed on the support substrate 20.

In another example of manufacture,, a release layer instead of the photothermal conversion film 21 may be used. The release layer, when irradiated with laser light, causes adhesive force to dissipate or decrease by abrasion phenomenon, or the film itself becomes dissipated or pulverized, allowing the support substrate 20 to be released from the other laminated material. For example, the release layer is made of amorphous silicon or ITO, and is irradiated with a laser with a wavelength of 355 nm or 308 nm.

### (Flexible Substrate Forming Step)

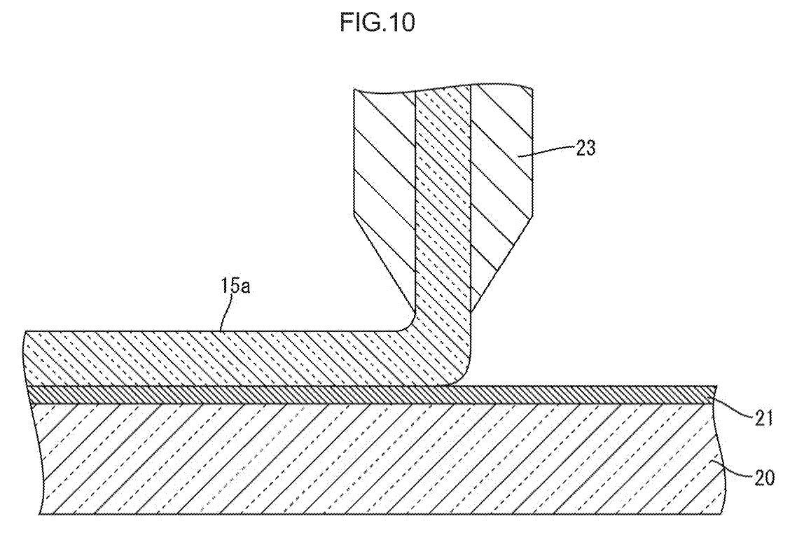

As described above, after the photothermal conversion film or the release layer 21 is formed on the support substrate 20, the flexible substrate 15B is formed so as to be laminated with the photothermal conversion film or the release layer 21. FIG. 10 is a diagram schematically illustrating the step of forming a SiO film 150 constituting the flexible substrate 15B according to the third embodiment on the photothermal conversion film 21.

The SiO film of the flexible substrate 15B includes, as described above, a film formed by SOG technology, such as a silicon oxide-based thin-film including organic matter obtained by thermally curing a liquid coating film containing a silanol compound based on an organic siloxane-based compound and including an alkyl group. The method of forming the SiO film 150, for example, may be the same as in the foregoing embodiments.

In the flexible substrate 15B, a film of organic material having high thermal resistance, such as a PI film, is additionally formed on the SOG film (SiO film) 150. In this case, preferably the PI to be used is a material that, through the framework structure of major materials and additives and the like, is able to transmit visible light as much as possible, has transparency, and has small phase difference.

For the PI film, for the purpose of maintaining adhesion directly over the support substrate, pretreatment is performed by, for example, exposing a hezamethyldisiloxane (HMDS) reagent to steam, or a silane coupling agent is applied using a spin coater, and then the PI film is formed. For the PI, a precursor polyamide acid (polyamic acid) dissolved in solvent is entirely applied using a slit coater or a spin coater and the like. The applied material is heated to 200° C. or above to perform irnidization, whereby the PI film is formed. The PI film has a film thickness that provides a required strength to the flexible substrate 15B eventually obtained. From the viewpoint of reducing phase difference, the smaller the film thickness, the better. Preferably, the film thickness may be 0.5 μm to 3 μm.

Generally, PI is a material that has high thermal resistance and chemical resistance. However, it is difficult to develop a material that can withstand the plasma for manufacturing a TFT element or the step of releasing a resist that is organic matter. Particularly, it is more difficult to develop a material with which visible light transparency and phase difference reduction can be achieved, both of which are indispensable in a liquid crystal display device. Thus, in another example of manufacture, by adopting the SOG/PI/SOG structure in which SOG material composed of SiO as a principal component and having high processing resistance is further coated/formed on the PI, it becomes possible to form a flexible substrate structure that can withstand the TFT element manufacturing.

Before the upper-layer SOG material is coated, in order to improve sticking force, adhesion improvement pretreatment is performed through, e.g., surface reforming by UV lamp irradiation or oxygen plasma exposure, and then coating is performed using, e.g., a slit coater or a spin coater. Thereafter, when heating process (baking process) is implemented, the coating film undergoes a reaction, whereby the silicon oxide-based thin-film composed of SiO as a principal component and including organic matter is obtained.

The thickness of the flexible substrate 15B is not particularly limited, and may be set as appropriate in accordance with the purpose. For example, the thickness is set to the order of 1 μm to 50 μm. The flexible substrate 15B is basically entirely formed with respect to the photothermal conversion film 21 on the support substrate 20.

### (Thin-Film Device Forming Step)

After the flexible substrate 15B is formed on the photothermal conversion film 21, as in the thin-film device forming step of the first embodiment, the constituent elements of the TFT-side thin-film layer 18 are patterned and formed in a predetermined shape on the flexible substrate 15B by utilizing known film formation technology, such as photolithography technology.

When the TFT-side thin-film layer 18 is formed on the flexible substrate 15B, the TFT array substrate 12 fixed to the support substrate 20 (thin-film device attached with a support substrate) is obtained.

Also with regard to the CF substrate 11, similarly to the case of the TFT array substrate 12 described above, the CF substrate 11 is formed via the photothermal conversion film 21 on the support substrate 20. That is, the photothermal conversion film 21 is formed on the support substrate 20, and, on the photothermal conversion film 21, the flexible substrate 14B with the two-layer structure of PI film 26/SiO film 140 is formed by a method similar to that in the case of the flexible substrate 15B described above. On the flexible substrate 14B, the CF-side thin-film layer 16 is formed, whereby the CF substrate 11 still fixed to the support substrate 20 is obtained. The flexible substrate 15B on the TFT array substrate-side and the flexible substrate 14B on the CF substrate side may not necessarily have the same configuration or film thickness, and may be implemented in other ways.

Also with regard to the CF substrate 11, similarly to the case of the TFT array substrate 12, a release layer instead of the photothermal conversion film may be used.

### (Affixing Step)

Then, as in the first embodiment, the CF substrate 11 and the TFT array substrate 12 each fixed to the support substrate 20 are affixed to each other so as to sandwich the liquid crystal layer 13. In this way, the CF substrate 11 and the TFT array substrate 12 are affixed to each other, with the substrates still fixed to the support substrate 20, which is stronger than the flexible substrates 14B, 15B, whereby the state of the liquid crystal display panel 10 is achieved. Accordingly, superior operatability, workability, transferability and the like of the CF substrate 11 and the TFT array substrate 12 are obtained. In addition, the manufacturing method of the present embodiment may be implemented using a conventional liquid crystal display device manufacturing apparatus and method.

### (Irradiating Step and Releasing Step)

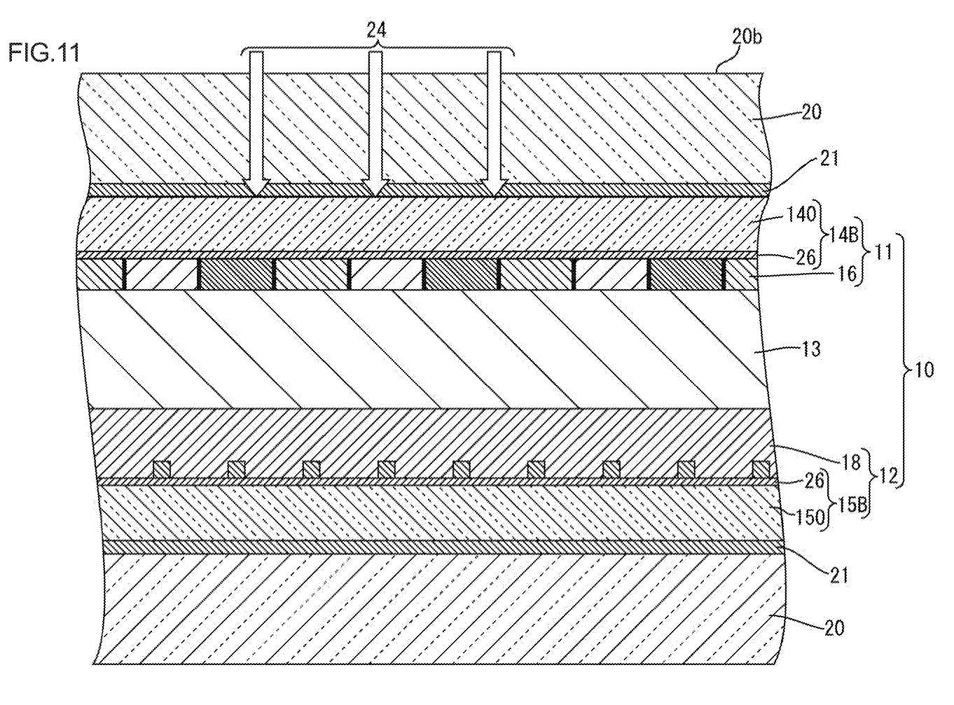

FIG. 11 is a diagram schematically illustrating the step in which, with the CF substrate 11 and the TFT array substrate 12 affixed to each other with the substrates still fixed to the support substrate 20, the laser light 24 is irradiated through the support substrate 20, and the absorbed optical energy is converted by the photothermal conversion film 21 into thermal energy to dissipate adhesive force at the interface with the flexible substrate 14B according to the third embodiment. As illustrated in FIG. 11, in order to release the support substrate 20 from the liquid crystal display panel 10, irradiation of the laser light 24 is performed.

In this step, the photothermal conversion film 21 on the CF substrate 11 side and the photothermal conversion film 21 on the TFT array substrate 12 side are respectively irradiated with the laser light 24 each through the support substrate 20. The light is absorbed and turned into heat, and the heat causes melting at the interface and an expansion/contraction difference due to a difference in linear expansion coefficient, whereby the support substrate 20 with one photothermal conversion film attached thereto is released from the flexible substrate 14B on the CF substrate 11 side. With a shape maintained by the support substrate 20 on the TFT array substrate 12 side that is stronger than the flexible substrates, a polarizing plate is affixed. Thereafter, laser irradiation is performed by a similar method from the support substrate 20 side of the TFT array 12, and the photothermal conversion film 21 and the support substrate 20 are released from the flexible substrate 15B on the TFT array substrate 12 side.

With regard to the type of the laser light 24, as in the first embodiment, a laser with a wavelength which passes through the support substrate 20 and at which sufficient energy for the releasing can be absorbed by the photothermal conversion film 21 is used. When the laser light 24 is irradiated toward the liquid crystal display panel 10, the laser light 24 may be irradiated from one side and then the other side, or the laser light 24 may be irradiated from both sides simultaneously.

When a release layer instead of the photothermal conversion film 21 is adopted, a laser configured to emit a wavelength that passes through the support substrate 20 and that is sufficiently absorbed, by the release layer is selected. When the laser light 24 is irradiated from the support substrate 20 side, the laser light 24 passes through the support substrate 20 and irradiates the release layer 21. The release layer 21 absorbs the laser light 24 and instantaneously evaporates (abrasion), whereby the release layer 21 is dissipated or pulverized, and the support substrate 20 and the flexible substrate 14B are separated. For example, when the release layer is made of amorphous silicon, a UV solid-state laser of 355 nm that is easily absorbed may be used for the irradiation.

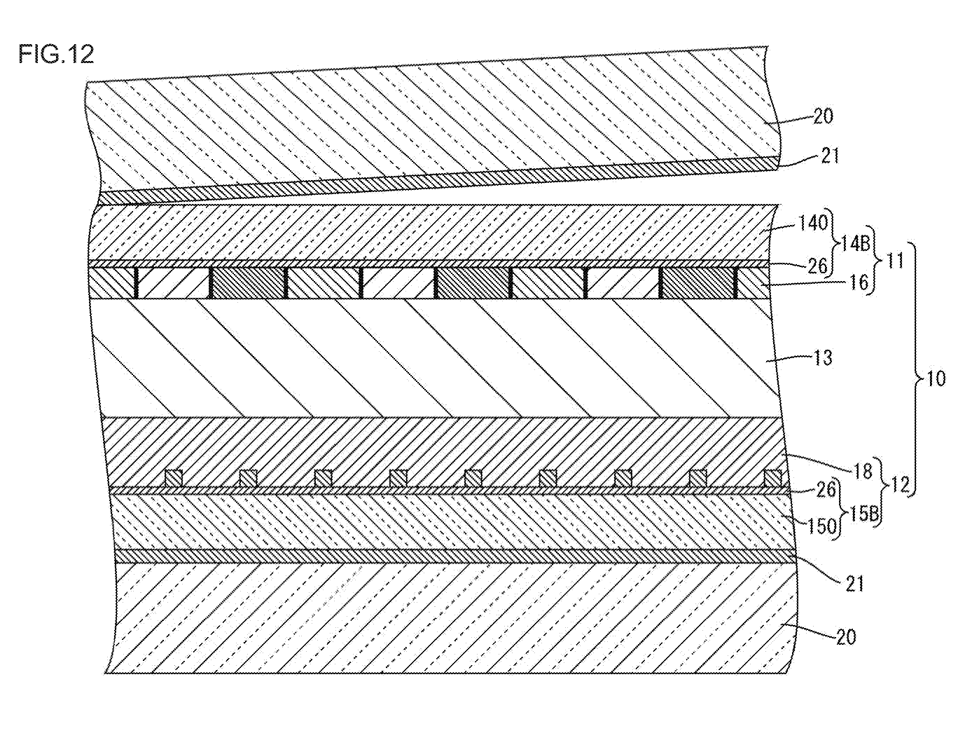

FIG. 12 is a diagram schematically illustrating, on the CF substrate 11 side, the step; in which the support substrate 20 is released from the flexible substrate 14B on the CF substrate 11 side according to the third embodiment. As described above, when the predetermined laser light 24 is irradiated from the outer side of the support substrate 20 toward the release layer 21 on the CF substrate 11 side, the laser light 24 passes through the support substrate 20 and reaches the photothermal conversion film 21. By the heat generated by the photothermal conversion film 21, the adhesion (fixing) between the support substrate 20 and the flexible substrate 14B is eliminated. As a result, the support substrate 20 can be easily released from the liquid crystal display panel 10 side.

Also with regard to the support substrate 20 on the TFT array substrate 12 side, similarly, the laser light 24 is irradiated from the outer side of the support substrate 20 toward the back surface of the support substrate 20 (outer surface) 20b to cause the photothermal conversion film 21 to generate heat. In this way, the support substrate 20 can be released from the flexible substrate 15B on the TFT array substrate 12 side.

After the support substrate 20 has been removed, the surfaces of the flexible substrates 14B, 15B may be cleaned, as appropriate, to remove residual material. Particularly, when a release layer instead of the photothermal conversion film 21 is adopted, debris may be produced by abrasion and visibility may be marred, and cleaning is often performed to remove residual material.

As described above, the liquid crystal display panel 10 intended for flexible display and equipped with the flexible substrates 14B, 15B with a small thickness on the order of 1 μm to 50 μm is obtained. On both outer sides of the liquid crystal display panel 10, the polarizing plates 17, 19 as illustrated in FIG. 1 for the first embodiment are eventually attached by means of an adhesive, such as pressure-sensitive adhesive.

### Other Embodiments

The present invention is not limited to the above embodiments explained in the above description and described with reference to the drawings. The following embodiments may be included in the technical scope of the present invention, for example.

(1) In the foregoing embodiments, the irradiating step and the releasing step are performed after the CF substrate 11 and the TFT array substrate 12 are affixed to each other. However, the present invention is not limited to such embodiments. For example, the irradiating step and the releasing step may be performed with a device substrate such as the CF substrate 11 not being affixed to another device substrate.

(2) In the foregoing embodiments, a liquid crystal display panel has been described as a display panel by way of example. The present invention, however, is not limited to such embodiments, and may also be applied in display panels in which other principles of display, such as organic EL display, are adopted.

(3) The method for manufacturing the device substrate (display panel) according to the present invention is not limited to the manufacture of one device substrate (display panel) at a time, but may be applied when a plurality of device substrates (display panels) connected in a matrix are manufactured at once.

### EXPLANATION OF SYMBOLS

10: Liquid crystal display panel (Display panel)

11: CF substrate (Device substrate)

12: TFT array substrate (Device substrate)

13: Liquid crystal layer

14, 15: Flexible substrate

16: CF-side thin-film layer (Thin-film device)

17: Polarizing plate

18: TFT-side thin-film layer (Thin-film, device)

18a: Barrier film

19: Polarizing plate

20: Support substrate

21: Photothermal conversion film

24: Laser light

26: Light absorb film

140, 150: SiO film

1. A device substrate comprising:
a visible light transmissive flexible substrate including one or a plurality of SiO films obtained by curing a coating liquid containing a silanol compound including an alkyl group in accordance with spin-on-glass technology; and
a thin-film device formed on the flexible substrate.

2. The device substrate according to claim 1, wherein the flexible substrate comprises a single SiO film in accordance with spin-on-glass technology.

3. The device substrate according to claim 1, wherein the flexible substrate includes a single SiO film in accordance with spin-on-glass technology, and a single thermal resistance organic film formed on, of two surfaces of the SiO film, a surface on the thin-film device side or a surface on the opposite side from the thin-film device side.

4. The device substrate according to claim 1, wherein the flexible substrate includes two SiO films in accordance with spin-on-glass technology and a single thermal resistance organic film interposed between the two SiO films.

5. The device substrate according to claim 1, wherein the flexible substrate includes a single SiO film in accordance with spin-on-glass technology and two thermal resistance organic films respectively formed on two surfaces of the SiO film.

6. The device substrate according to claim 3, wherein the thermal resistance organic film comprises polyimide or polyamide.

7. A liquid crystal display apparatus including a color filter substrate comprising the device substrate according to claim 1.

8. A liquid crystal display apparatus including a thin-film transistor array substrate comprising the device substrate according to claim 1.

9. A method for manufacturing a device substrate for a liquid crystal display apparatus having a visible light transmissive flexible substrate and a thin-film device formed on the flexible substrate, the method comprising:
a photothermal conversion film forming step in which a photothermal conversion film is formed on a plate surface of a support substrate configured to transmit laser light and configured to support the device substrate, the photothermal conversion film generating heat by absorption of the laser light and being released from a film directly thereabove by the heat;
a flexible substrate forming step in which the flexible substrate is formed on the photothermal conversion film by coating a coating liquid for forming the flexible substrate on the photothermal conversion film, and curing a coating film comprising the coating liquid;
a thin-film device forming step in which the thin-film device is formed on the flexible substrate;
an irradiating step in which laser light is irradiated from a surface side of the support substrate on which the thin-film device is not formed toward the photothermal conversion film, and in which adhesive force between the photothermal conversion film and the flexible substrate is dissipated or reduced; and
a releasing step in which, after the adhesive force of the photothermal conversion film is dissipated and the like, the support substrate and the photothermal conversion film are released from the device substrate.

10. The method for manufacturing a device substrate for a liquid crystal display apparatus according to claim 9, wherein the photothermal conversion film comprises a high melting-point metal or a high melting-point alloy including at least one selected from the group consisting of Ti, Mo, Ta, and W.

11. A method for manufacturing a device substrate for a liquid crystal display apparatus having a visible light transmissive flexible substrate and a thin-film device formed on the flexible substrate, the method comprising:
a release layer forming step of forming a release layer on a plate surface of a support substrate configured to transmit laser light and configured to support the device substrate, the release layer being dissipated or pulverized by abrasion phenomenon of laser light;
a flexible substrate forming step in which the flexible substrate is formed on the release layer using a coating liquid for forming the flexible substrate on the release layer, and curing a coating film comprising the coating liquid;
a thin-film device forming step in which the thin-film device is formed on the flexible substrate, and the device substrate fixed to the support substrate via the release layer is obtained;
an irradiating step in which laser light is irradiated from a surface side of the support substrate on which the thin-film device is not formed toward the release layer, and adhesive force between the release layer and the flexible substrate is dissipated or reduced; and
a releasing step in which, after the adhesive force of the release layer is dissipated, the support substrate and the release layer are released from the device substrate.

12. The method for manufacturing a device substrate for a liquid crystal display apparatus according to claim 11, wherein the release layer comprises a material that has large absorption of light of 300 nm to 400 nm selected from the group consisting of amorphous silicon, ITO, IZO, and In—Ga—Zn—O.

13. The method for manufacturing a device substrate for a liquid crystal display apparatus according to claim 9, wherein, in the flexible substrate forming step, the coating liquid contains a silanol compound including an alkyl group, and the coating film forms a SiO film containing an organic component after a heating reaction.
